(19) United States
(12) Patent Application Publication
(10) Pub. No.: US 2026/0086160 A1
(43) Pub. Date: Mar. 26, 2026

(54) VEHICLE MONITORING CONTROL SYSTEM

(71) Applicant: TOYOTA JIDOSHA KABUSHIKI KAISHA, Toyota-shi (JP)

(72) Inventors: Keigo MATSUBARA, Nagoya-shi (JP); Kyohei SUZUMURA, Nagoya-shi (JP)

(73) Assignee: TOYOTA JIDOSHA KABUSHIKI KAISHA, Toyota-shi (JP)

(21) Appl. No.: 19/327,534

(22) Filed: Sep. 12, 2025

(30) Foreign Application Priority Data
Sep. 20, 2024 (JP) 2024-163380

(51) Int. Cl. G01R 31/3835; G01R 31/00; G07C 5/08

(52) U.S. Cl. CPC G01R 31/3835; G01R 31/007; G07C 5/0808

(57) ABSTRACT

A monitoring control system for a vehicle configured to prevent an erroneous determination of an occurrence of a failure in the vehicle. The monitoring control system comprises a sensor that outputs a signal in accordance with an electric voltage applied thereto from an electric power source. The monitoring control system is configured to: determine whether an output voltage of the electric power source is equal to or higher than a predetermined voltage; determine whether a predetermined condition to destabilize the output voltage of the electric power source is satisfied; and determine the occurrence of a failure in the vehicle based on the output signal of the sensor, in a situation where the output voltage of the electric power source is equal to or higher than the predetermined voltage and the predetermined condition is not satisfied.

### CROSS-REFERENCE TO RELATED APPLICATIONS

The present disclosure claims the benefit of Japanese Patent Application No. 2024-163380 filed on September 20, 2024 with the Japanese Patent Office, the disclosure of which is incorporated herein by reference in its entirety.

### BACKGROUND

### Field of the Invention

The present disclosure relates to a vehicle monitoring control system that determines an occurrence of a failure in a vehicle.

### Discussion of the Related Art

JPH1113872 describes a shift control apparatus for a belt-driven continuously variable transmission having a primary pulley connected to an engine, a secondary pulley connected to a drive wheel, and a belt wound around the primary pulley and the secondary pulley. In a vehicle equipped with the continuously variable transmission of this kind, a speed ratio between the engine and the drive wheels is varied continuously by changing a running radius of the belt of the continuously variable transmission. According to the teachings of JPH1113872, a shift mode may be selected from an automatic upshift in which an upshift is executed automatically according to an increase of the vehicle speed, and a foot-release upshift in which an upshift is executed at a time when a foot of a driver is released from an accelerator pedal. The shift control device according to JPH1113872 is configured execute the automatic upshift and the foot-release upshift at different shift speeds, so as to prevent erroneous determination of the automatic upshift during execution of the foot-release upshift. To this end, the shift control apparatus taught by JPH1113872 calculates an objective primary rotation speed based on a vehicle speed and a throttle opening, and then calculates a final objective transmission ratio based on the objective primary rotation speed and a secondary speed. Thereafter, the shift control apparatus calculates a transient objective transmission ratio to achieve the final objective transmission ratio, and calculates an objective ratio deviation between the final objective transmission ratio and the transient objective transmission ratio. Specifically, the shift control apparatus determines the foot-release upshift when a rate of change in the objective primary rotation speed per time is smaller than a negative shift decision value or when the objective ratio deviation is equal to or less than an automatic upshift decision value.

As described above, the shift control apparatus described in JPH1113872 calculates the objective primary rotation speed, the final objective transmission ratio etc. based on the detected vehicle speed and the throttle opening. Usually, the sensors detecting those parameters transmit signals according to a voltage supplied thereto from a power supply. That is, when the power supply voltage is reduced or unstable, the output signal of the sensor does not increase or fluctuates, and as a result, a detected value of the sensor may deviate from an actual behavior of the vehicle. In such a case, the objective primary rotation speed and the final objective transmission ratio may not be determined appropriately. In addition, the transmission ratio and the shift speed may not be set properly in accordance with traveling conditions and operations of the vehicle.

In the prior art, there is known a vehicle having a transmission controller for setting a speed ratio of a transmission based on detection values of various sensors, and a monitoring controller for determining an occurrence of a failure based on the detection values of the sensors. The monitoring controller of this kind is configured to prevent the transmission controller from setting an improper speed ratio due to malfunction of electronic components provided in the vehicle. For example, when a speed ratio set by the transmission controller increases abruptly due to a sudden change in a vehicle speed detected by the sensor, the monitoring controller determines whether or not such an abrupt increase in the speed ratio is caused by a malfunction of the electronic component. If such an abrupt increase in the speed ratio occurs due to a malfunction of the electronic component, the driver is notified of the malfunction of the electronic component by lighting-up a warning lamp, and fail-safe control is executed. As described above, when the power supply voltage is low or unstable, detection accuracies of the sensors are reduced, and as a result, the monitoring controller may erroneously determine an occurrence of a failure in the vehicle.

### SUMMARY

An object of the present disclosure is to provide a monitoring control system for a vehicle configured to prevent an erroneous determination of an occurrence of a failure in the vehicle.

In order to achieve the above-explained objective, according to the exemplary embodiment of the present disclosure, there is provided a monitoring control system for a vehicle that has a sensor adapted to output a signal in accordance with an electric voltage applied thereto from an electric power source, and that determines an occurrence of a failure in the vehicle based on the output signal of the sensor. The monitoring control system is provided with a controller that determines the occurrence of a failure in the vehicle. According to the exemplary embodiment of the present disclosure, the controller comprises: a voltage determiner that determines whether or not an output voltage of the electric power source is equal to or higher than a predetermined voltage; a condition determiner that determines whether or not a predetermined condition to destabilize the output voltage of the electric power source is satisfied; and a failure determiner that determines the occurrence of a failure in the vehicle based on the output signal of the sensor, in a case that the voltage determiner determines that the output voltage of the electric power source is equal to or higher than the predetermined voltage, and that the condition determiner determines that the predetermined condition to destabilize the output voltage of the electric power source is not satisfied.

In a non-limiting embodiment, the failure determiner may be configured to determine that the failure occurs in the vehicle when at least any one of an amount of change in the output signal of the sensor and a time change rate of the output signal of the sensor is equal to or greater than a predetermined threshold value.

In a non-limiting embodiment, the monitoring control system may further comprise an electronic device other than the sensor to which an electric power is supplied from the electric power source. In addition, the predetermined condition may include a condition that the electric power required to activate the electronic device is equal to or greater than a predetermined power.

In a non-limiting embodiment, the monitoring control system may further comprise a transmission that changes a speed ratio between a prime mover of the vehicle and a drive wheel. In addition, the sensor may include a speed sensor that detects a rotational speed of a rotary member arranged in an output side of the transmission.

Thus, according to the exemplary embodiment of the present disclosure, the monitoring control system determines an occurrence of a failure in the vehicle based on the output signal of the sensor, in a situation where the output voltage of the electric power source is equal to or higher than the predetermined voltage and the predetermined condition to destabilize the output voltage of the electric power source is not satisfied. According to the exemplary embodiment of the present disclosure, therefore, a determination of an occurrence of a failure in the vehicle will not be made erroneously based on an improper detection value or a fluctuated detection value transmitted from the sensor due to a fluctuation or reduction in the output voltage of the electric power source.

### BRIEF DESCRIPTION OF THE DRAWINGS

Features, aspects, and advantages of exemplary embodiments of the present disclosure will become better understood with reference to the following description and accompanying drawings, which should not limit the disclosure in any way.

FIG. 1 is a schematic illustration showing one example of a structure of a vehicle having the monitoring control system according to the exemplary embodiment of present disclosure;

FIG. 2 is a block diagram showing functions of the monitoring control system according to the exemplary embodiment of the present disclosure; and

FIG. 3 is a flowchart showing one example of a routine executed by the monitoring control system according to the exemplary embodiment of the present disclosure.

### DETAILED DESCRIPTION OF THE PREFERRED EMBODIMENT(S)

An exemplary embodiment of the present disclosure will now be explained with reference to the accompanying drawings. Note that the embodiment shown below is merely an example of the present disclosure, which should not limit the present disclosure.

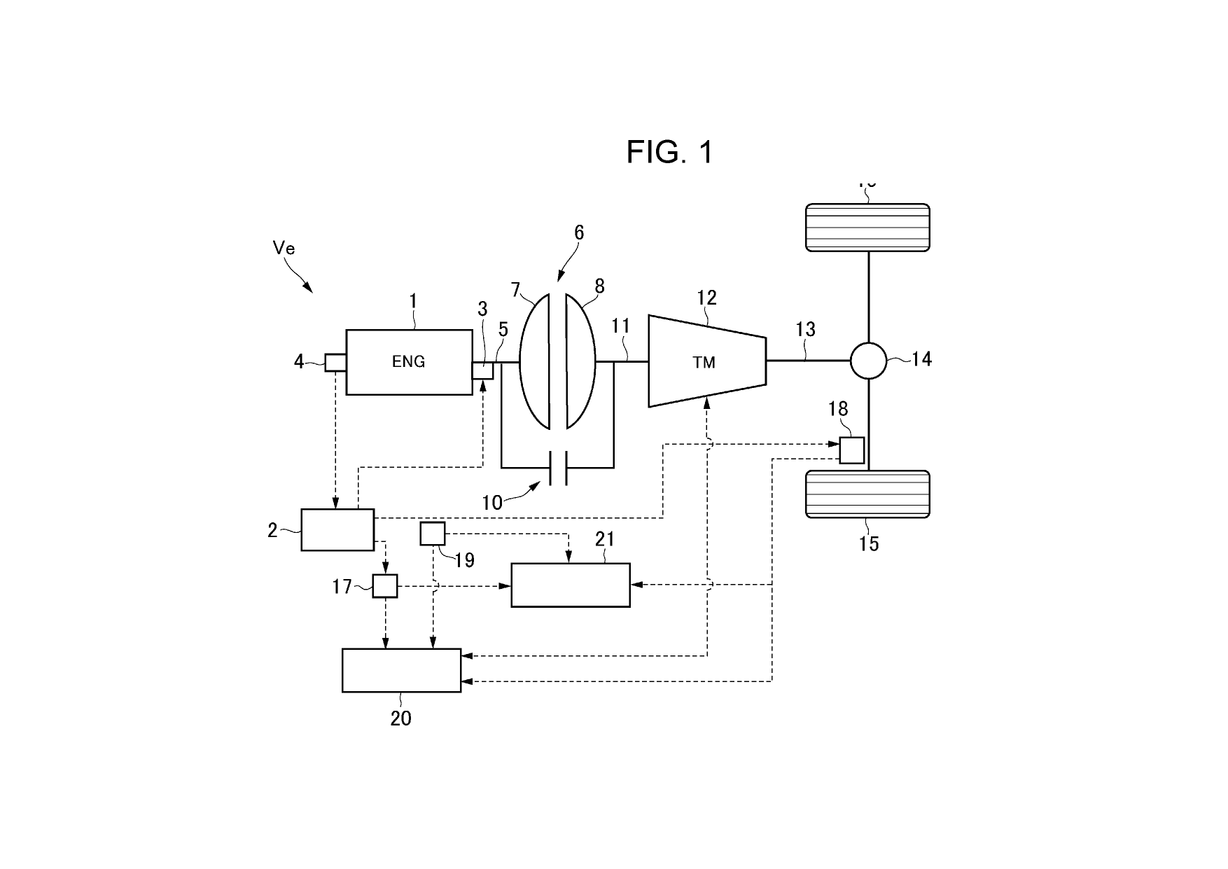

FIG. 1 schematically illustrates one example of the vehicle Ve according to the exemplary embodiment of present disclosure. The vehicle Ve shown in FIG. 1 comprises an engine (ENG) 1 that serves as a prime mover. As the conventional internal combustion engines, the engine 1 generates power by burning a mixture of air and fuel such as gasoline and diesel. Specifically, the engine 1 is provided with a throttle valve for controlling an amount of air introduced into cylinders, a fuel injector for injecting fuel into the cylinders, and an ignition plug for igniting an air-fuel mixture. The throttle valve, the fuel injector, and the injection plug are actuated by supplying electric power to actuators of those devices from an electric power source 2.

In order to crank the stopping engine 1, the vehicle Ve further comprises a starter motor 3. The starter motor 3 is also activated by supplying the electric power thereto from the electric power source 2.

As the electric power sources arranged in conventional vehicles, the electric power source 2 is charged by an electric power generated by a generator such as an alternator 4.

A torque converter 6 is connected to an output shaft 5 of the engine 1. The torque converter 6 includes a pump impeller 7 connected to the output shaft 5 of the engine 1, and a turbine runner 8 opposed to the pump impeller 7. The torque converter 6 may be provided with a stator for redirecting a fluid discharged from the turbine runner 8. In addition, a lockup clutch 10 is arranged in the vehicle Ve to adjust a speed difference between the pump impeller 7 and the turbine runner 8 to a desired value, and to rotate the pump impeller 7 and the turbine runner 8 integrally.

An automatic transmission (referred to as TM in FIG. 1) 12 is connected to an output shaft 11 of the torque converter 6. For example, a geared automatic transmission that changes a speed ratio stepwise, a belt driven continuously variable transmission that changes a speed ratio continuously by changing a running radius of a belt, and a toroidal continuously variable transmission that changes a speed ratio continuously by changing an inclination angle of a power roller may be adopted as the automatic transmission 12. In addition, a hybrid continuously variable transmission mechanism in which an engine, a motor, and an output shaft are connected through a differential mechanism, and a speed of the engine is continuously changed by changing a rotational speed of the motor may also be adopted instead of the automatic transmission 12.

A pair of drive wheels 15 is connected to an output shaft 13 of the automatic transmission 12 through a differential gear unit 14.

The automatic transmission 12 changes a speed ratio according to a required drive force to propel the vehicle Ve, and a speed of the vehicle Ve. To this end, for example, the vehicle Ve is provided with an accelerator sensor 17 for detecting a position of an accelerator pedal (not shown), and a wheel speed sensor 18 for detecting a rotational speed of each of the drive wheels 15. Electric voltage is applied to the accelerator sensor 17 and the wheel speed sensor 18 from the electric power source 2, and the accelerator sensor 17 and the wheel speed sensor 18 transmit signals (voltage or current) in accordance with the voltage applied thereto. Therefore, the vehicle Ve shown in FIG. 1 is provided with a voltmeter 19 for detecting an output voltage of the electric power source 2. In the exemplary embodiment of the present disclosure, accordingly, the wheel speed sensor 18 serves as a "sensor", and the drive wheels 15 serves as a "rotary member".

In addition, the vehicle Ve is provided with various sensors including a crank angle sensor for detecting a rotational speed (rotational angle) of the engine 1, a turbine speed sensor for detecting a rotational speed of the turbine runner 8, a throttle opening sensor for detecting an opening degree of the throttle valve, a shift position sensor for detecting a position of the shift lever, and a sensor for detecting an operating condition of an ignition switch (or a start switch).

In order to determine a speed ratio of the automatic transmission 12 based on the detected values of the accelerator sensor 17, the wheel speed sensor 18 etc., the vehicle Ve is provided with a transmission controller 20. The transmission controller 20 comprises a microcomputer. Specifically, the transmission controller 20 is configured to calculate a target speed ratio of the automatic transmission 12 based on incident signals using a calculation formula and a map installed therein, and transmit a command signal to an actuator of the automatic transmission 12 so as to achieve the calculated target speed ratio.

For example, a shift map for determining a speed ratio is installed in the transmission controller 20, and in the shift map, a position of the accelerator pedal and a vehicle speed are employed as parameters to determine the speed ratio. As described above, a position of the accelerator pedal is detected by the accelerator sensor 17, and a speed of the vehicle Ve is calculated based on a wheel speed detected by the wheel speed sensor 18. Based on these parameters, the transmission controller 20 determines a speed ratio of the automatic transmission 12 with reference to the shift map. Instead, a speed ratio of the automatic transmission 12 may also be determined based on a target engine speed and a speed of the vehicle Ve. In this case, the transmission controller 20 calculates a drive power required to propel the engine 1 based on a required drive force governed by a position of the accelerator pedal and a speed of the vehicle Ve, and calculates a target engine speed at which the drive power is generated in the optimally fuel-efficient manner. Then, the transmission controller 20 determines the target speed ratio of the automatic transmission 12 based on the target engine speed and the speed of the vehicle Ve. Here, the means for determining a speed ratio of the automatic transmission 12 may be the same as the means for setting a speed ratio of the automatic transmission arranged in the conventional vehicle, and is not limited to the above means.

In addition, the vehicle Ve shown in FIG. 1 is further provided with a monitoring controller 21 for determining an occurrence of a failure in the vehicle Ve. The monitoring controller 21 also comprises a microcomputer. Specifically, the monitoring controller 21 is configured to determine an occurrence of a failure in the vehicle Ve based on a signal transmitted thereto from a predetermined sensor, and to transmit a signal representing a determination result to e.g., an actuator that turns on (or blinks) a warning lamp (not shown) or another control device that performs fail-safe control.

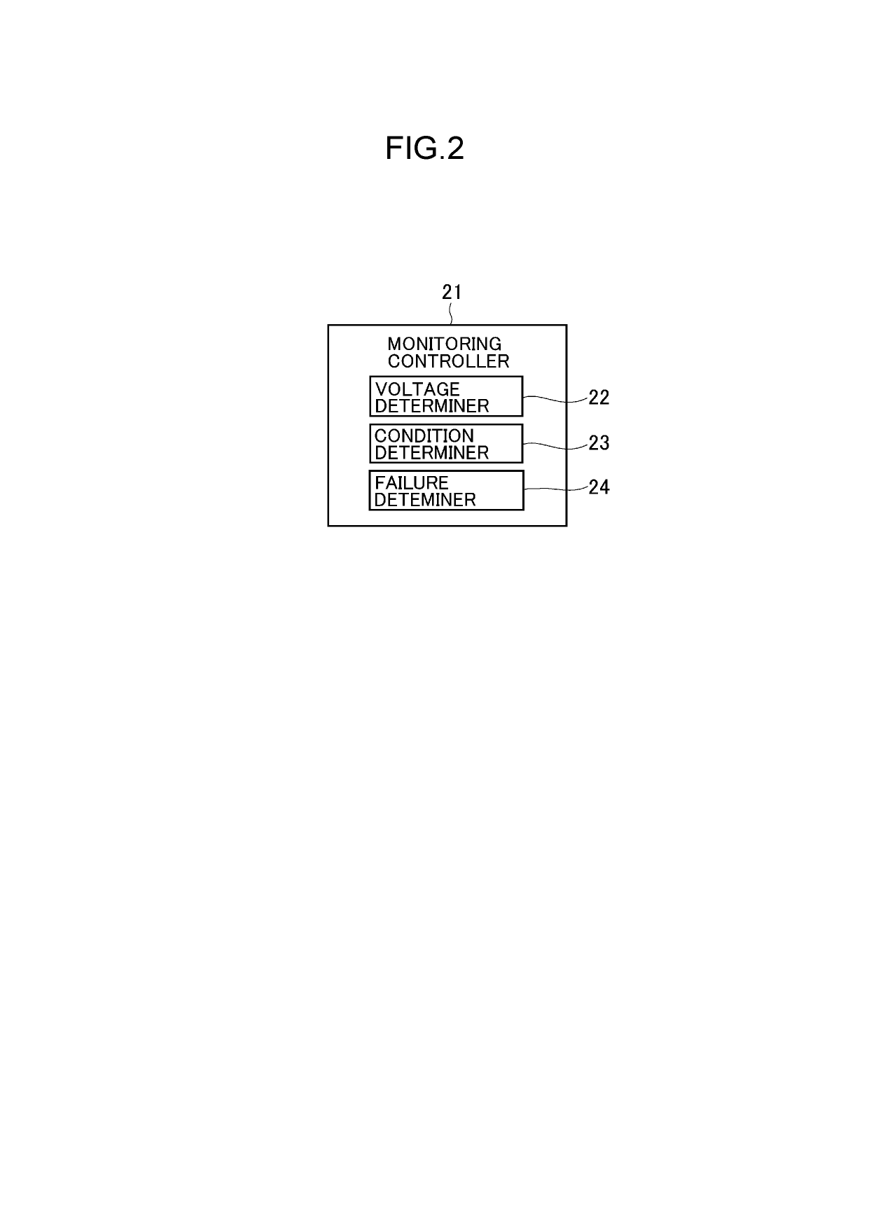

FIG. 2 is a block diagram showing functions of the monitoring controller 21. As shown in FIG. 2, the monitoring controller 21 comprises a voltage determiner 22, a condition determiner 23, and a failure determiner 24.

The voltage determiner 22 is configured to determine whether or not an output voltage of the electric power source 2 is equal to or higher than a predetermined voltage. Specifically, an output voltage of the electric power source 2 detected by the voltmeter 19 is transmitted to the voltage determiner 22 in the form of detection signal. For example, the predetermined voltage is set equal to or higher than a voltage required to be applied to the wheel speed sensor 18 so as to detect the number of revolutions of the drive wheels 15 accurately. That is, the voltage determiner 22 determines whether or not an accurate detection value can be transmitted from the sensor.

The condition determiner 23 is configured to determine whether or not a predetermined condition to destabilize the output voltage of the electric power source 2 is satisfied. For example, the predetermined condition is satisfied when a change in the output voltage of the electric power source 2 is increased to a predetermined amount or greater, or when a time rate of change in the output voltage of the electric power source 2 is increased to a predetermined rate or greater. When a large power is required to activate the electronic devices other than the sensor, a large amount of electric power is discharged from the electric power source 2, and as a result, the output voltage of the electric power source 2 may significantly drop to lower than the predetermined voltage. For example, when cranking the engine 1, the electric power is supplied from the electric power source 2 to drive the starter motor 3, and as a result, the output voltage of the electric power source 2 may decrease to lower than the predetermined voltage. Such condition that the output voltage of the electric power source 2 is reduced to lower than the predetermined voltage as a result of supplying the electric power from the electric power source 2 to the electronic device other than the sensor is stored in the condition determiner 23, and the condition determiner 23 determines whether or not such condition is satisfied.

Note that the voltage of the electric power source 2 gradually decreases in the situation where the engine 1 is stopped, and hence the output voltage of the electric power source 2 may be lower than the predetermined voltage until a predetermined time has elapsed from the startup of the engine 1. Therefore, the voltage determiner 22 may be adapted to determine that the output voltage of the electric power source 2 is equal to or lower than the predetermined voltage immediately after the startup of the engine. In addition, the condition determiner 23 may be adapted to determine a satisfaction of the above-described predetermined condition until a predetermined period of time has elapsed from the startup of the engine.

The failure determiner 24 is configured to determine an occurrence of a failure in the vehicle Ve based on incident signals transmitted from the sensors arranged in the vehicle Ve. To this end, for example, the failure determiner 24 compares the previous value of the wheel speed stored in the monitoring controller 21 with the current value of the wheel speed transmitted from the wheel speed sensor 18 to the monitoring controller 21. Consequently, if an amount of change or a rate of change of the wheel speed from the previous value to the current value is greater than an amount of change or a rate of change that will not occur in the normal condition of the vehicle Ve, the failure determiner 24 determines that a failure has occurred in the electronic component or the like arranged in the vehicle Ve.

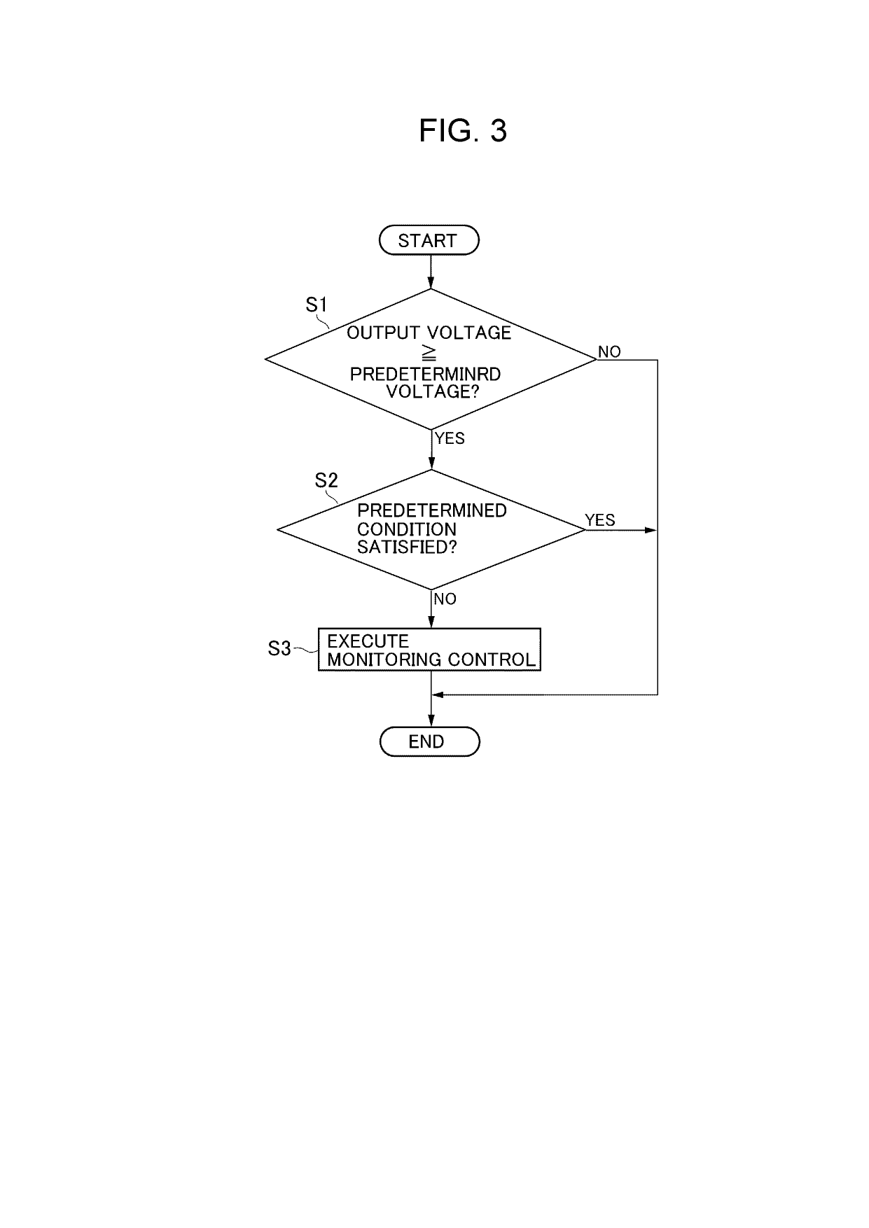

FIG. 3 is a flowchart for explaining an example of a routine executed by the monitoring controller 21. At step S1, the voltage determiner 22 determines whether or not the output voltage of the electric power source 2 is equal to or higher than the predetermined voltage.

If the output voltage of the power source 2 is lower than the predetermined voltage so that the answer of step S1 is NO, the sensor e.g., the wheel speed sensor 18 is not allowed to output a detection value properly. In this situation, if an occurrence of a failure in the vehicle Ve is determined based on the detected value of the sensor, the monitoring controller 21 may erroneously determine the occurrence of a failure in the vehicle Ve even though the failure does not occur in the vehicle Ve. In this case, therefore, the routine returns without determining an occurrence of a failure in the vehicle Ve based on the detected value of the sensor. Instead, in a case that the answer of step S1 is NO, an occurrence of a failure in the vehicle Ve may be determined based on a parameter other than the detected value of the sensor. In this case, for example, an occurrence of a failure in the vehicle Ve may be determined based on a fact that the sensor outputs voltage or current.

By contrast, if the output voltage of the electric power source 2 is equal to or higher than the predetermined voltage so that the answer of step S1 is YES, the routine progresses to step S2 to determine whether or not the predetermined condition to destabilize the output voltage of the electric power source 2 is satisfied. At step S2, specifically, the condition determiner 23 determines whether or not the electric power required to activate the electronic device other than the sensor is equal to or greater than the predetermined electric power, or the engine 1 is being cranked. For example, such determination may be made based on a fact that the controller other than the monitoring controller 21 is transmitting a signal for executing a control to satisfy the predetermined condition.

In a case that the predetermined condition to destabilize the output voltage of the electric power source 2 is satisfied so that the answer of step S2 is YES, the output voltage of the electric power source 2 may decrease abruptly from a level higher than the predetermined voltage to a level lower than the predetermined voltage even if the wheel speed is not changing, and consequently the detected value of the wheel speed sensor 18 may decrease abruptly. In this case, in order to prevent an erroneous determination of an occurrence of a failure in the vehicle Ve, the routine returns without determining an occurrence of a failure in the vehicle Ve based on the detected value of the sensor.

By contrast, if the predetermined condition to destabilize the output voltage of the electric power source 2 is not satisfied so that the answer of step S2 is NO, the routine progresses to step S3 to execute the monitoring control for determining an occurrence of a failure in the vehicle Ve by the failure determiner 24 based on the detected value of the sensor, and thereafter the routine returns. At step S3, for example, the failure determiner 24 determines that a failure occurs in the electronic component arranged in the vehicle Ve if a difference between the previous value of the wheel speed stored in the monitoring controller 21 and the current value of the wheel speed transmitted to the monitoring controller 21 from the wheel speed sensor 18 is equal to or greater than the predetermined difference. That is, when an amount of change in the output signal of the sensor or a time change rate of the output signal of the sensor is equal to or greater than the threshold value, the failure determiner 24 determines that a failure occurs in the electronic component or the like arranged in the vehicle Ve. When the occurrence of a failure in the vehicle Ve is determined during execution of the monitoring control, the occurrence of the failure may be notified to the driver or occupant by transmitting a signal to a notification device such as a warning lamp (not shown). In addition, the fail-safe control may be executed by transmitting a signal representing occurrence of a failure to another controller or the like.

Thus, the monitoring control for determining an occurrence of a failure in the vehicle Ve based on the detected value of the sensor is executed in the situation where the output voltage of the electric power source 2 is equal to or higher than the predetermined voltage, and the condition to destabilize the output voltage of the electric power source 2 is not satisfied. Therefore, the monitoring controller 21 may be prevented from making an erroneous determination of an occurrence of a failure in the vehicle Ve based on an improper detection value or a fluctuated detection value transmitted from the sensor due to a fluctuation or reduction in the output voltage of the electric power source 2.

Note that the monitoring control system according to the embodiment of the present disclosure may also be applied to a vehicle other than a vehicle equipped with an engine as a prime mover. For example, the monitoring control system according to the embodiment of the present disclosure may also be applied to an electric vehicle having a motor as a prime mover, and a hybrid vehicle in which a prime mover included an engine and a motor. Further, the monitoring control system according to the embodiment of the present disclosure may be configured to determine an occurrence of a failure in the vehicle based on a signal transmitted from a sensor detecting an input speed of the automatic transmission or a signal transmitted from another sensor, instead of the signal transmitted from the sensor detecting an output speed of the automatic transmission.

What is claimed is:

1. A monitoring control system for a vehicle that has a sensor adapted to output a signal in accordance with an electric voltage applied thereto from an electric power source, and that determines an occurrence of a failure in the vehicle based on the output signal of the sensor, comprising:
a controller that determines the occurrence of a failure in the vehicle,
wherein the controller comprises:
a voltage determiner that determines whether or not an output voltage of the electric power source is equal to or higher than a predetermined voltage;
a condition determiner that determines whether or not a predetermined condition to destabilize the output voltage of the electric power source is satisfied; and
a failure determiner that determines the occurrence of a failure in the vehicle based on the output signal of the sensor, in a case that the voltage determiner determines that the output voltage of the electric power source is equal to or higher than the predetermined voltage, and that the condition determiner determines that the predetermined condition to destabilize the output voltage of the electric power source is not satisfied.

2. The monitoring control system as claimed in claim 1, wherein the failure determiner is configured to determine that the failure occurs in the vehicle when at least any one of an amount of change in the output signal of the sensor and a time change rate of the output signal of the sensor is equal to or greater than a predetermined threshold value.

3. The monitoring control system as claimed in claim 1, further comprising:
an electronic device other than the sensor to which an electric power is supplied from the electric power source,
wherein the predetermined condition includes a condition that the electric power required to activate the electronic device is equal to or greater than a predetermined power.

4. The monitoring control system as claimed in claim 1, further comprising:
a transmission that changes a speed ratio between a prime mover of the vehicle and a drive wheel,
wherein the sensor includes a speed sensor that detects a rotational speed of a rotary member arranged in an output side of the transmission.
